(19) United States
(12) Patent Application Publication
(10) Pub. No.: US 2022/0364217 A1
(43) Pub. Date: Nov. 17, 2022

(54) DEPOSITION MASK AND MANUFACTURING METHOD OF ORGANIC ELECTRONIC DEVICE

(71) Applicant: CANON KABUSHIKI KAISHA, Tokyo (JP)

(72) Inventors: Takahiro Yajima, Kanagawa (JP); Yutaka Setomoto, Kanagawa (JP); Shinichiro Watanabe, Kanagawa (JP)

(21) Appl. No.: 17/743,588

(22) Filed: May 13, 2022

(30) Foreign Application Priority Data
May 14, 2021 (JP) 2021-082705

(51) Int. Cl. C23C 14/04; H01L 51/00; H01L 51/56

(52) U.S. Cl. CPC C23C 14/042; H01L 51/0011; H01L 51/56

(57) ABSTRACT

A deposition mask according to the present invention includes a first substrate that is a single-crystal substrate, wherein a first region that is at least a portion of the first substrate, includes a plurality of rectangular areas each of which has one or a plurality of openings, a substrate thickness in the rectangular area is smaller than a substrate thickness in an area that is a part of the first region and is not the rectangular area, and an angle θ1 between a side of the rectangular area and a cleavage direction of the first substrate is in a range of 0°<θ1<90°.

### BACKGROUND OF THE INVENTION

### Field of the Invention

The present invention relates to a deposition mask and a manufacturing method of an organic electronic device.

### Description of the Related Art

An organic EL (electroluminescence) element is a light-emitting display element. The organic EL element has a thin film multilayer structure, which enables high-speed response. An organic EL panel (display panel with an array of organic EL elements) is lightweight and capable of excellent display of moving images, and is attracting attention. Organic EL panels are used in display apparatuses such as a flat panel display (FPD), small displays for electronic viewfinders (EVF), and so on.

Many organic EL panels are manufactured by a process in which organic materials are deposited on a target substrate by using a vacuum deposition apparatus with resistance heating. For full color organic EL panels, it is necessary to produce minute display elements of R (red), G (green), and B (blue) with high precision. For this reason, mask vapor deposition methods are employed, in which three types of organic materials corresponding to R, G, and B are deposited at respective desired positions (different positions), using metal masks. Display elements can also be called pixels. Since an organic EL panel is a light-emitting display panel, display elements can also be called light-emitting elements.

Production of finer organic EL panels (organic electronic devices) requires finer metal masks, meaning that metal masks need to be made thinner and processed with higher precision. However, thinner metal masks easily warp, and suffer a larger plastic deformation when subjected to tension, which makes high-precision processing difficult. Moreover, metal masks have a thermal expansion coefficient largely different from that of a target substrate made of glass, silicon and the like, because of which there occurs a significant misalignment between the metal mask and the target substrate by the heating during vapor deposition.

Japanese Patent Application Publication No. 2005-42133 discloses the use of a silicon substrate as a deposition mask. Silicon substrates can be processed using semiconductor production techniques such as photolithography and dry etching and allow for processing with high precision to the scale of microns. Moreover, silicon substrates have a thermal expansion coefficient comparable to that of the target substrate, whereby no large misalignment occurs.

However, conventional deposition masks that use single-crystal silicon substrates have low mechanical strength.

### SUMMARY OF THE INVENTION

The present invention provides a deposition mask made of a single-crystal substrate and having high mechanical strength, and further provides a high-quality organic electronic device.

The present invention in its first aspect provides a deposition mask including a first substrate that is a single-crystal substrate, wherein a first region that is at least a portion of the first substrate, includes a plurality of rectangular areas each of which has one or a plurality of openings, a substrate thickness in the rectangular area is smaller than a substrate thickness in an area that is a part of the first region and is not the rectangular area, and an angle θ1 between a side of the rectangular area and a cleavage direction of the first substrate is in a range of 0°<θ1<90°.

The present invention in its second aspect provides a deposition mask including a single-crystal substrate, wherein in at least a portion of the single-crystal substrate, a plurality of openings arrayed in a matrix, and an angle φ between each of a row direction and a column direction, in which the plurality of openings are arrayed, and a cleavage direction of the single-crystal substrate is in a range of 0°<φ<90°.

The present invention in its third aspect provides a manufacturing method of an organic electronic device, the method including: placing a deposition mask to face a target substrate; and depositing an organic material on the target substrate through the deposition mask, wherein the deposition mask includes a first substrate that is a single-crystal substrate, a first region that is at least a portion of the first substrate, includes a plurality of rectangular areas each of which has one or a plurality of openings, a substrate thickness in the rectangular area is smaller than a substrate thickness in an area that is a part of the first region and is not the rectangular area, and an angle θ1 between a side of the rectangular area and a cleavage direction of the first substrate is in a range of 0°<θ1<90°.

Further features of the present invention will become apparent from the following description of exemplary embodiments with reference to the attached drawings.

### BRIEF DESCRIPTION OF THE DRAWINGS

FIG. 1A and FIG. 1B are diagrammatic plan views of a deposition mask according to a first embodiment;

FIG. 1C is a diagrammatic cross-sectional view of the deposition mask according to the first embodiment;

FIG. 2 is a diagrammatic cross-sectional view of a manufacturing process of an OLED according to the first embodiment;

FIG. 3A is a diagrammatic plan view of a deposition mask according to a second embodiment;

FIG. 3B is a diagrammatic cross-sectional view of the deposition mask according to the second embodiment;

FIG. 4A and FIG. 4B are diagrammatic plan views of a deposition mask according to a third embodiment;

FIG. 4C is a diagrammatic cross-sectional view of the deposition mask according to the third embodiment;

FIG. 5A and FIG. 5B are diagrammatic plan views of a deposition mask according to a fourth embodiment;

FIG. 5C is a diagrammatic cross-sectional view of the deposition mask according to the fourth embodiment;

FIG. 6A and FIG. 6B are diagrammatic plan views of a deposition mask according to a fifth embodiment;

FIG. 6C is a diagrammatic cross-sectional view of the deposition mask according to the fifth embodiment;

FIG. 7A and FIG. 7B are diagrammatic plan views of a deposition mask according to a sixth embodiment;

FIG. 7C and FIG. 7D are diagrammatic cross-sectional views of the deposition mask according to the sixth embodiment;

FIG. 8A is a diagrammatic plan view of a deposition mask according to a seventh embodiment;

FIG. 8B is a diagrammatic cross-sectional view of the deposition mask according to the seventh embodiment;

FIG. 8C and FIG. 8D are diagrammatic plan views illustrating part of a pixel area in the seventh embodiment to a larger scale;

FIG. 8E is a diagrammatic view illustrating an angle in relation to the seventh embodiment (angle between a row direction or column direction of a plurality of pixel apertures and a cleavage direction);

FIG. 9A is a diagrammatic plan view of a conventional deposition mask; and

FIG. 9B is a diagrammatic cross-sectional view of the conventional deposition mask.

### DESCRIPTION OF THE EMBODIMENTS

Hereinafter modes for carrying out the present invention will be described with reference to the drawings. It should be understood that the present invention can be implemented in various different manners and should not be interpreted as being limited to the contents of the embodiment described below. Some of the drawings may depict the width, thickness, shape, etc., of each part in a diagrammatic representation for the sake of clearer explanation. These only illustrate examples and do not limit the interpretation of the present invention.

### Conventional Example

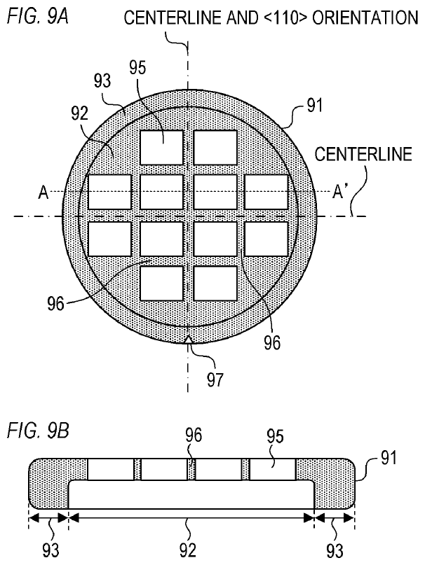

Before describing the embodiment of the present invention, a conventional example will be described. FIG. 9A is a diagrammatic plan view of a conventional deposition mask 91 viewed from below. FIG. 9B is a diagrammatic cross-sectional view illustrating a cross section of a plane passing line A-A′ in FIG. 9A and perpendicular to the deposition mask 91.

The deposition mask 91 is made of one single-crystal silicon substrate. The surface of the deposition mask 91 is a (100) plane. That is, the direction perpendicular to the surface of the deposition mask 91 coincides with the <100> orientation. A notch 97 is formed on an end face of the deposition mask 91 at a point indicating the <110> orientation on the (100) plane. The surface of the deposition mask 91 is either an upper surface or a lower surface of the deposition mask 91, and can also be referred to as substrate surface.

Monocrystalline silicon has a diamond-like crystal structure. When subjected to an external force, the single-crystal silicon easily splits along planes where atomic bonds are weak. When bonds are weak in a certain direction, the bonds in directions perpendicular thereto are also weak. Namely, when cleavage occurs easily in a certain direction, it easily occurs also in directions perpendicular thereto.

The deposition mask 91 includes a first region 92 and a second region 93 that surrounds the first region 92. In the first region 92 of the deposition mask 91, a plurality of openings 95 are formed, each corresponding to each of a plurality of chips (e.g., a plurality of organic electronic devices). The opening 95 is rectangular in plan view. The deposition mask 91 has strips 96 between adjacent openings 95. The strip 96 is formed by one side of one of two openings 95 adjoining each other and one side of the other one of these two openings 95. Here, sides refer to sides illustrated in a diagrammatic plan view. One side of an opening 95 in a diagrammatic plan view is, when viewed three-dimensionally, a side wall of the opening 95, which can also be considered an inner wall.

When an external force is applied to the deposition mask 91, the force concentrates on strips 96. If the strips 96 are thick enough relative to the openings 95, the strips 96 will not break even when an external force is applied to the deposition mask 91. If, however, the strips 96 are thin relative to the openings 95, the strips 96 may break when an external force is applied to the deposition mask 91 because the strips 96 are weak in mechanical strength.

The sides forming the strips 96 (sides of the openings 95) of the deposition mask 91 run parallel or perpendicular to the <110> orientation along which cleavage can easily occur, i.e., cleavage direction. Therefore the strips 96 have relatively low mechanical strength, and the strips 96 are prone to defects such as breaking, cracking, and chipping. Such defects in strips 96 may generate particles (foreign substance), in which case a defect originating from the particles may arise in the organic electronic device. This may result in yield reduction of the organic electronic devices.

The notations of crystal planes and crystal orientations (crystal directions) are now described. Crystal planes and crystal orientations can be represented using Miller indices.

A crystal orientation can be written [uvw], for example. [uvw] represents the orientation (direction) of a vector from a given lattice point in the crystal to another given lattice point P. Taking the above given lattice point (not the lattice point P) as origin O, the vector OP from the origin O to the lattice point P of a unit lattice having lengths a, b, c in x-, y-, and z-axes, respectively, is represented by ua+vb+wc. A plurality of crystal orientations equivalent to [uvw] from the viewpoint of symmetry can be collectively denoted <uvw>.

A crystal plane can be written (uvw). (uvw) represents a plane that passes l/u on the x-axis, l/v on the y-axis, and l/w on the z-axis. A plurality of crystal planes equivalent to (uvw) from the viewpoint of symmetry can be collectively denoted {uvw}.

### First Embodiment

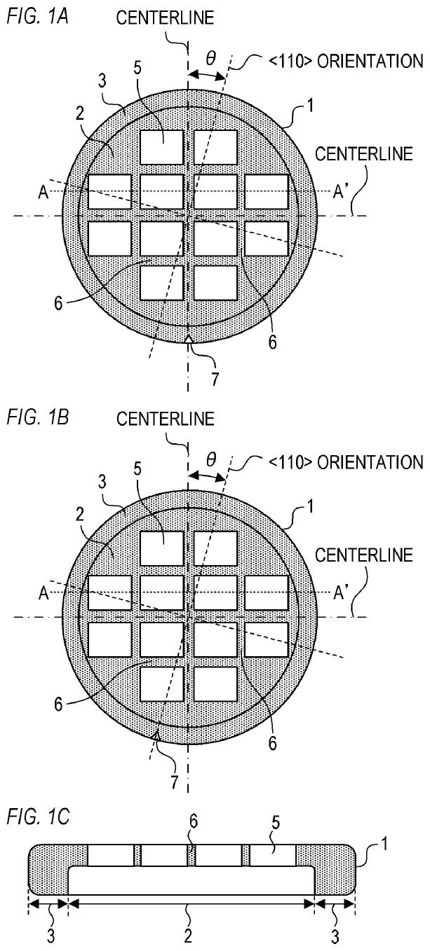

Hereinafter, a first embodiment of the present invention will be described. FIG. 1A and FIG. 1B are diagrammatic plan views of a deposition mask 1 according to this embodiment viewed from below. FIG. 1C is a diagrammatic cross-sectional view illustrating a cross section of a plane passing line A-A′ in FIG. 1A or FIG. 1B and perpendicular to the deposition mask 1.

The deposition mask 1 is made of a single mask substrate that is a single-crystal silicon substrate. The deposition mask 1 (mask substrate) includes a first region 2 and a second region 3 that surrounds the first region 2. In the first region 2 of the deposition mask 1, a plurality of openings 5 are formed, each corresponding to each of a plurality of chips (e.g., a plurality of organic electronic devices). In this embodiment, the first region 2 is circular, and the second region 3 is annular. Therefore, the deposition mask 1 is circular. The deposition mask 1 has a diameter (outer shape of the second region 3) of 100 mm to 300 mm, for example.

The deposition mask 1 is thin in the first region 2 so as to allow for production of high-resolution organic electronic devices. The deposition mask 1 is thicker in the second region 3 than in the first region 2 so as to have sufficient strength. For example, the thickness of the deposition mask 1 in the first region 2 is 1 μm to 100 μm, and the thickness of the deposition mask 1 in the second region 3 is 100 μm to 775 μm.

The deposition mask 1 can be composed of a semiconductor material such as single-crystal silicon. For example, a single-crystal silicon substrate or SOI (Silicon On Insulator) substrate can be used for the deposition mask 1. In this embodiment, the deposition mask 1 is a silicon wafer. The deposition mask 1 may be made of one type of material, or several types of materials.

As illustrated in FIG. 1A and FIG. 1B, the opening 5 has a rectangular shape in plan view, and the deposition mask 1 has strips 6 between adjacent openings 5. A rectangular shape refers to a quadrilateral such as a rectangle or square, for example. The strip 6 is formed by one side of one of two openings 5 adjoining each other and one side of the other one of these two openings 5. In this embodiment, sides refer to sides illustrated in the diagrammatic plan view.

The surface of the deposition mask 1 is a (100) plane. That is, the direction perpendicular to the surface of the deposition mask 1 coincides with the <100> orientation. The sides forming the strips 6 (sides of the openings 5) of the deposition mask 1 run parallel or perpendicular to centerlines indicated by dash dot lines in FIG. 1A and FIG. 1B.

As illustrated in FIG. 1A and FIG. 1B, the <110> orientations on the (100) plane are inclined to the above-mentioned centerlines at an angle θ (0°<θ<90°). Namely, the sides forming the strips 6 (sides of the openings 5) of the deposition mask 1 are inclined at an angle θ (0°<θ<90°) to the <110> orientations that are easy to cleave, i.e., cleavage directions.

In other words, the plurality of openings 5 are aligned along a first direction inclined at the angle θ to the cleavage direction of the deposition mask 1 and a second direction perpendicular to the first direction, and the openings 5 have sides parallel to the first direction and sides parallel to the second direction. The first direction and second direction are the directions of the centerlines.

This way, the mechanical strength of the deposition mask 1 (strips 6) can be enhanced, so that occurrence of defects in the deposition mask 1 can be reduced. This, in turn, enables production of high-quality organic electronic devices.

The mechanical strength is relatively high when the angle θ to the cleavage direction is in the range of 10°≤θ≤35°. The mechanical strength is highest when the angle θ to the cleavage direction is in the range of 26.5±5°. Therefore, the angle θ should preferably be in the range of 10°≤θ≤35°, and more preferably be in the range of 26.5±5°.

Now a manufacturing method of the deposition mask 1 will be described. In the case of FIG. 1A, a notch 7 is formed on an end face of the deposition mask 1 (substrate before openings 5 etc. are formed) at a position shifted by an angle θ from the point indicating the <110> orientation on the (100) plane. In the case of FIG. 1B, a notch 7 is formed on an end face of the deposition mask 1 (substrate before openings 5 etc. are formed) at the point indicating the <110> orientation on the (100) plane. Semiconductor substrates with notches indicating the <110> orientations are commercially available, i.e., marketed products can be used in the case of FIG. 1B.

Next, a mask pattern of a plurality of openings 5 is formed on the upper surface of the deposition mask 1 by photolithography, using the notch 7 as a reference, and the plurality of portions corresponding to the openings 5 are etched from the upper side of the deposition mask 1. This way, the thickness of the deposition mask 1 is reduced from the upper side in the plurality of portions corresponding to the openings 5.

Lastly, a mask pattern of the first region 2 is formed on the lower surface of the deposition mask 1 by photolithography, and the first region 2 is etched from the lower side of the deposition mask 1. This way, the thickness of the deposition mask 1 is reduced from the lower side in the first region 2. The plurality of portions corresponding to the openings 5 are etched through, becoming the openings 5. The width of the openings 5 may be selected freely in the range of, for example, 0.1 mm to 100 mm.

Etching may be wet etching that uses an alkaline solution, or dry etching such as reactive ion etching (RIE) that uses a reactive gas. The thickness of the deposition mask 1 may be reduced by machining with the use of a grinder or the like, in which case the process of photolithography for forming a mask pattern can be omitted.

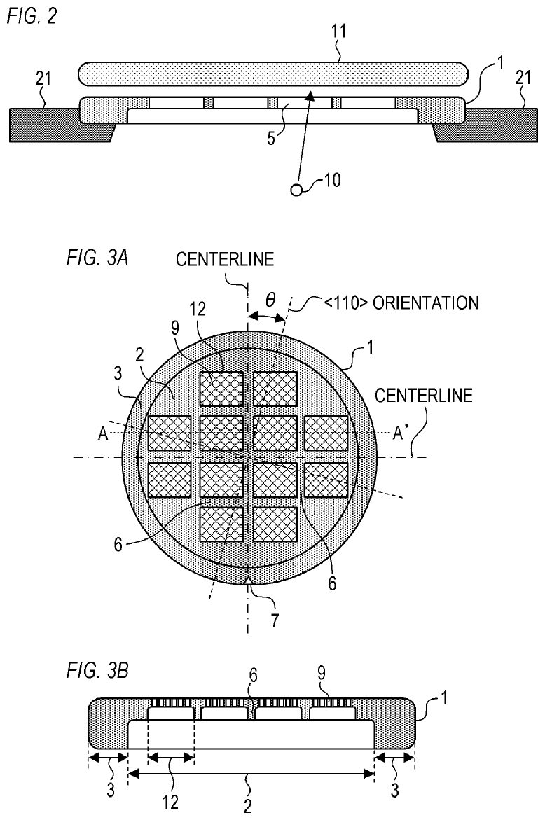

Part of the manufacturing process of an OLED (Organic Light-Emitting Diode), which is one example of organic electronic device, will be described with reference to FIG. 2. FIG. 2 is a diagrammatic cross-sectional view similar to FIG. 1C illustrating (part of) the manufacturing process of an OLED. FIG. 2 illustrates a process of depositing an organic material on a target substrate through the deposition mask 1.

As shown in FIG. 2, the deposition mask 1 is disposed such that the upper surface of the deposition mask 1 faces the lower surface of a target substrate 11. The deposition mask 1 is fixed to a mask holder 21, and can be moved in three directions, the X direction (width), Y direction (depth), and Z direction (height), by moving the mask holder 21. After the deposition mask 1 has been positioned relative to the target substrate 11, a material source (not shown) below the deposition mask 1 (opposite side from the target substrate 11) is heated to cause the target particles 10 to fly out from the material source. The flying target particles 10 pass through the openings 5 of the deposition mask 1 and reach the target substrate 11. The target particles 10 thus deposit onto the target substrate 11.

Here, the target particles 10 are an organic light-emitting material. An organic material that emits white light, for example, may be selected for the target particles 10. In this case, an OLED configured to change white light into red, green, or blue light with the use of color filters can be manufactured.

As will be described later, the rectangular area forming each opening 5 may have a plurality of apertures therein. Here, these apertures each correspond to pixels, and therefore will be hereinafter referred to as pixel apertures. In the case where a plurality of pixel apertures are formed in the rectangular areas forming the openings 5, organic materials that respectively emit red light (R), green light (G), and blue light (B) may be selected for the target particles 10. These three types of organic materials need to be deposited (to make thin films) at respective desired positions (different positions). Therefore, three deposition masks 1 respectively corresponding to R, G, B, specifically, three deposition masks 1 having different pixel aperture positions, are used.

### Second Embodiment

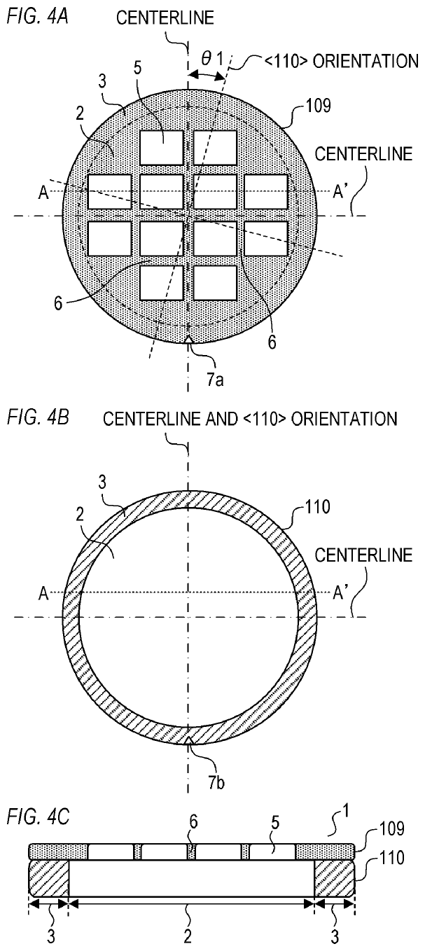

Hereinafter, a second embodiment of the present invention will be described with reference to FIG. 3A and FIG. 3B. FIG. 3A is a diagrammatic plan view of a deposition mask 1 according to this embodiment viewed from below. FIG. 3B is a diagrammatic cross-sectional view illustrating a cross section of a plane passing line A-A′ in FIG. 3A and perpendicular to the deposition mask 1. In this embodiment, there are pixel areas 12 where a plurality of pixel apertures 9 are arranged instead of the rectangular areas forming openings 5 in the first embodiment. The pixel areas 12 (rectangular areas) as a whole are not openings.

The thickness of the deposition mask 1 in the pixel areas 12 of the first region 2 is thinner than the thickness of the deposition mask 1 in the remaining areas of the first region 2. Thus the deposition mask 1 has strips 6 between adjacent pixel areas 12.

The deposition mask 1 is a silicon wafer in this embodiment, too. The surface of the deposition mask 1 is a (100) plane, and the sides forming the strips 6 (sides of the pixel areas 12) run parallel or perpendicular to centerlines indicated by dash dot lines in FIG. 3A. As illustrated in FIG. 3A, the <110> orientations on the (100) plane are inclined to the above-mentioned centerlines at an angle θ (0°<θ<90°). Namely, the sides forming the strips 6 (sides of the pixel areas 12) of the deposition mask 1 are inclined at an angle θ (0°<θ<90°) to the <110> orientations that are easy to cleave, i.e., cleavage directions.

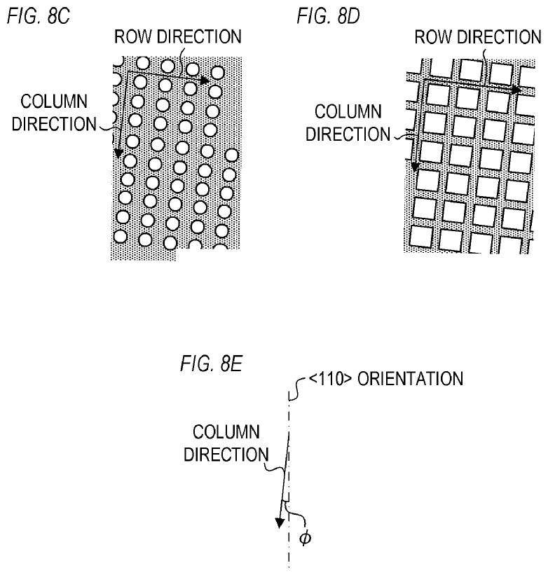

This way, similarly to the first embodiment, the mechanical strength of the deposition mask 1 (strips 6) can be enhanced, so that occurrence of defects in the deposition mask 1 can be reduced. This, in turn, enables production of high-quality organic electronic devices. To achieve high mechanical strength between the pixel apertures 9, it is preferable that none of the sides of the pixel apertures 9 coincides with the cleavage direction of the deposition mask 1 in a plane parallel to the deposition mask 1. Specifically, all of the sides of the plurality of pixel apertures 9 should preferably be inclined at an angle θ (0°<θ<90°) to the cleavage direction of the deposition mask 1, as illustrated in FIG. 8D which will be referred to in relation to a seventh embodiment.

The manufacturing method of the deposition mask 1 will now be described. First, a notch 7 is formed on an end face of the deposition mask 1 (substrate before pixel areas 12 and pixel apertures 9 etc. are formed) at a position shifted by the angle θ from the point indicating the <110> orientation on the (100) plane.

Next, a mask pattern of a plurality of pixel apertures 9 is formed on the upper surface of the deposition mask 1 by photolithography, using the notch 7 as a reference, and the plurality of portions corresponding to the pixel apertures 9 are etched from the upper side of the deposition mask 1. This way, the thickness of the deposition mask 1 is reduced from the upper side in the plurality of portions corresponding to the pixel apertures 9.

A mask pattern of the first region 2 is then formed on the lower surface of the deposition mask 1 by photolithography, and the first region 2 is etched from the lower side of the deposition mask 1. This way, the thickness of the deposition mask 1 is reduced from the lower side in the first region 2 to several tens μm to several hundreds μm.

Lastly, a mask pattern of the pixel areas 12 is formed on the lower surface of the deposition mask 1 by photolithography, and the pixel areas 12 are etched from the lower side of the deposition mask 1. This way, the thickness of the deposition mask 1 is reduced from the lower side in the pixel areas 12 to several μm to several tens μm. The plurality of portions corresponding to the pixel apertures 9 are etched through, becoming the pixel apertures 9. The width of the pixel apertures 9 may be selected freely in the range of, for example, 0.5 μm to 100 μm. The shape of the pixel apertures 9 may be selected freely from polygons such as a rectangle or hexagon, or a circle or any other shapes. The layout of the pixel apertures 9 may be selected freely from a stripe pattern, square pattern, delta pattern, PenTile matrix, Bayer pattern, and so on.

### Third Embodiment

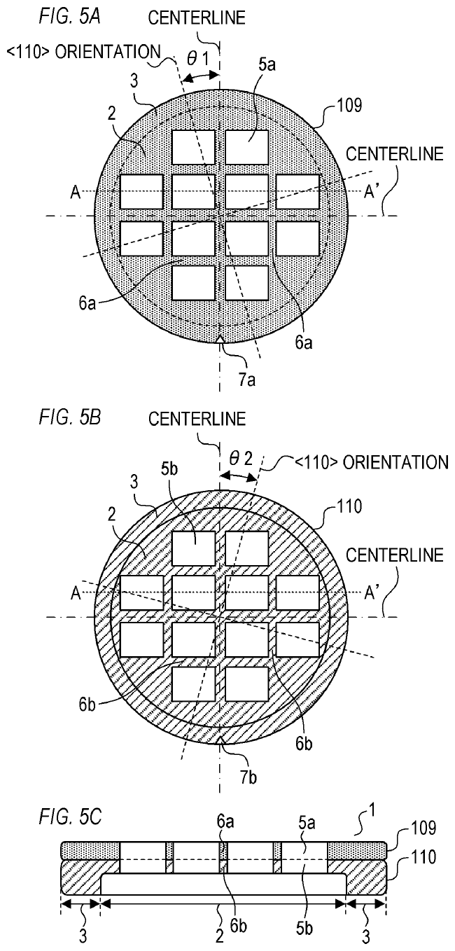

Hereinafter, a third embodiment of the present invention will be described with reference to FIG. 4A to FIG. 4C. In this embodiment, the deposition mask 1 is a stack of a plurality of substrates. FIG. 4A is a diagrammatic plan view of a first wafer 109 (first substrate) forming the deposition mask 1 viewed from below, and FIG. 4B is a diagrammatic plan view of a second wafer 110 (second substrate) forming the deposition mask 1 viewed from below. FIG. 4C is a diagrammatic cross-sectional view illustrating a cross section of a plane passing line A-A′ in FIG. 4A and FIG. 4B and perpendicular to the deposition mask 1.

The first wafer 109 and second wafer 110 are both single-crystal substrates. In this embodiment, they are silicon wafers. As illustrated in FIG. 4A, the first wafer 109 includes a first region 2, where openings 5 are formed. As illustrated in FIG. 4B, the second wafer 110 forms a second region 3. As illustrated in FIG. 4C, the deposition mask 1 has a layered structure composed of the first wafer 109 and second wafer 110, the second wafer 110 supporting the first wafer 109.

In this case, the deposition mask 1 (entire stack of the first wafer 109 and second wafer 110) may be considered the mask substrate, or, the first wafer 109 may be considered the mask substrate and the second wafer 110 may be considered a frame substrate. The first region 2 may be any region that is at least a portion of the surface of the first wafer 109, and may be the entire surface of the first wafer 109. The deposition mask 1 may be a stack of three or more substrates.

The deposition mask 1 composed of a plurality of substrates makes processing easier. For example, the first wafer 109 can be readily obtained by forming openings 5 in a flat substrate, without the processing of reducing the thickness of the first region 2 relative to the second region 3. Since the processing is easy, the first wafer 109 can be made even thinner. When the strips 6 have a large height (thickness) and the openings 5 or pixel apertures 9 are small, the openings are harder for the target particles to pass through, and are readily clogged up by the target particles adhering thereto. The height of the strips 6 can be made smaller by making the first wafer 109 thinner, which allows for size reduction of openings such as the openings 5 and pixel apertures 9. Moreover, using different materials for the plurality of substrates constituting the deposition mask 1 allows for adjustment of a difference in stress generated in the plurality of substrates, or adjustment of a difference in thermal expansion coefficient between the substrates.

The surface of the first wafer 109 and the surface of the second wafer 110 are both (100) planes. As illustrated in FIG. 4A, a notch 7a is formed on an end face of the first wafer 109 at a position shifted by an angle θ1 (0°<θ1<90°) from the point indicating the <110> orientation on the (100) plane. As illustrated in FIG. 4B, a notch 7b is formed on an end face of the second wafer 110 at the point indicating the <110> orientation on the (100) plane. A common semiconductor substrate is used for the second wafer 110.

As mentioned above, the second wafer 110 is the part that forms the second region 3, and no openings 5 are formed in the second wafer 110. The first wafer 109 is formed with a plurality of openings 5 such that the sides forming the strips 6 (sides of the openings 5) are inclined at an angle θ1 to the cleavage direction of the first wafer 109 (<110> orientation on the (100) plane).

This way, the mechanical strength of the deposition mask 1 (strips 6) can be enhanced, so that occurrence of defects in the deposition mask 1 can be reduced. This, in turn, enables production of high-quality organic electronic devices.

In this embodiment, the first wafer 109 and second wafer 110 are overlapped such that the position of the notch 7a of the first wafer 109 matches the position of the notch 7b of the second wafer 110. This way, the angle θ2 between the sides of the openings 5 and the cleavage direction of the second wafer 110 (<110> orientation on the (100) plane) is made different from the angle θ1 between the sides of the openings 5 and the cleavage direction of the first wafer 109 (<110> orientation on the (100) plane). In this embodiment, the angle θ2 is 0°.

### Fourth Embodiment

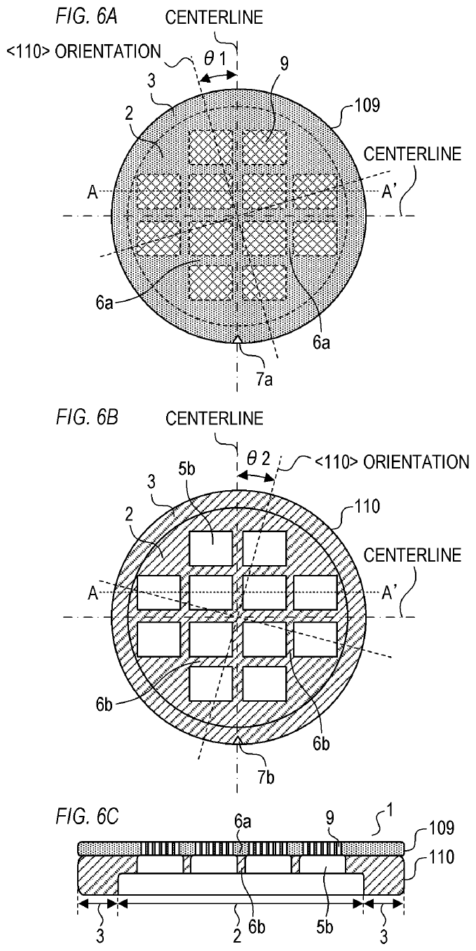

Hereinafter, a fourth embodiment of the present invention will be described with reference to FIG. 5A to FIG. 5C. FIG. 5A is a diagrammatic plan view of a first wafer 109 forming the deposition mask 1 according to this embodiment viewed from below, and FIG. 5B is a diagrammatic plan view of a second wafer 110 forming the deposition mask 1 viewed from below. FIG. 5C is a diagrammatic cross-sectional view illustrating a cross section of a plane passing line A-A′ in FIG. 5A and FIG. 5B and perpendicular to the deposition mask 1.

The first wafer 109 and second wafer 110 are both single-crystal substrates. In this embodiment, they are silicon wafers. Similarly to the third embodiment, the first wafer 109 includes a first region 2, where a plurality of openings 5a are formed. Unlike the third embodiment, the second wafer 110 includes a first region and a second region 3, i.e., a plurality of openings 5b are formed in the second wafer 110, too. As illustrated in FIG. 5C, the deposition mask 1 has a layered structure composed of the first wafer 109 and second wafer 110.

The surface of the first wafer 109 and the surface of the second wafer 110 are both (100) planes. As illustrated in FIG. 5A, a notch 7a is formed on an end face of the first wafer 109 at a position shifted by an angle θ1 (0°<θ1<90°) from the point indicating the <110> orientation on the (100) plane. As illustrated in FIG. 5B, a notch 7b is formed on an end face of the second wafer 110 at a position shifted by an angle θ2 (0°<θ2<90°) from the point indicating the <110> orientation on the (100) plane. The angle θ2 is an angle in the opposite direction from the angle θ1. In this embodiment, the angle θ1 is a clockwise angle from the <110> orientation, and the angle θ2 is a counterclockwise angle from the <110> orientation.

The first wafer 109 is formed with a plurality of openings 5a such that the sides forming the strips 6a of the first wafer 109 (sides of the openings 5a) are inclined at the angle θ1 to the cleavage direction of the first wafer 109 (<110> orientation on the (100) plane). The second wafer 110 is formed with a plurality of openings 5b such that the sides forming the strips 6b of the second wafer 110 (sides of the openings 5b) are inclined at the angle θ2 to the cleavage direction of the second wafer 110 (<110> orientation on the (100) plane).

This way, the mechanical strength of the strips 6a of the first wafer 109 can be enhanced, and the mechanical strength of the strips 6b of the second wafer 110 can be enhanced.

In this embodiment, the first wafer 109 and second wafer 110 are overlapped such that the position of the notch 7a of the first wafer 109 matches the position of the notch 7b of the second wafer 110. This way, the first wafer 109 and second wafer 110 are laminated so that the cleavage direction of the first wafer 109 and the cleavage direction of the second wafer 110 are different. The openings 5a and openings 5b fully overlap each other in the same orientation, and the strips 6a and strips 6b also fully overlap each other in the same orientation. One pair of openings 5a and 5b is equivalent to the opening 5 of the first embodiment. One pair of strips 6a and 6b is equivalent to the strip 6 of the first embodiment.

This (making the cleavage directions of the plurality of substrates different) can enhance the mechanical strength of the deposition mask 1 (strips 6) even more, so that occurrence of defects in the deposition mask 1 can be reduced even more. For example, the mechanical strength of the deposition mask 1 (strips 6) against twist and torsion can be enhanced. This, in turn, enables more reliable production of high-quality organic electronic devices.

### Fifth Embodiment

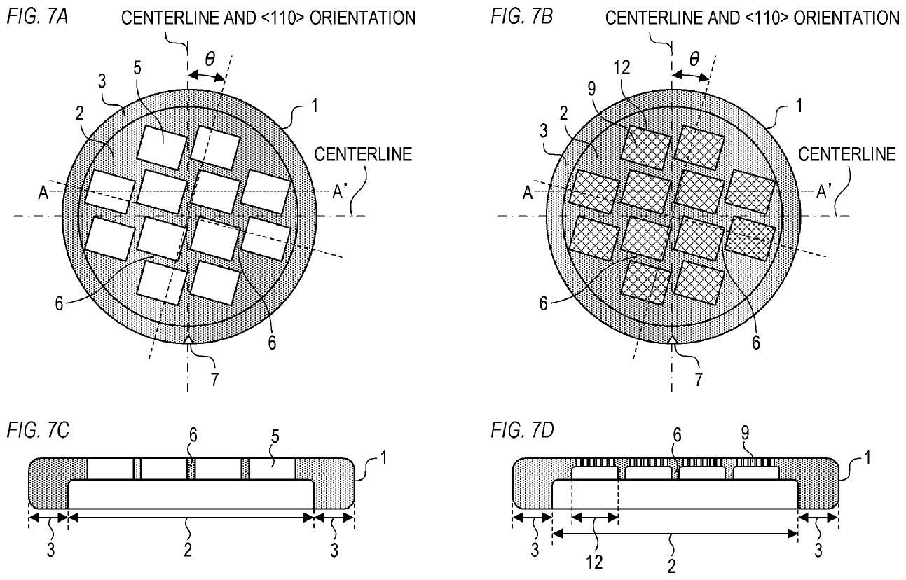

Hereinafter, a fifth embodiment of the present invention will be described with reference to FIG. 6A to FIG. 6C. FIG. 6A is a diagrammatic plan view of a first wafer 109 forming the deposition mask 1 according to this embodiment viewed from below, and FIG. 6B is a diagrammatic plan view of a second wafer 110 forming the deposition mask 1 viewed from below. FIG. 6C is a diagrammatic cross-sectional view illustrating a cross section of a plane passing line A-A′ in FIG. 6A and FIG. 6B and perpendicular to the deposition mask 1.

The first wafer 109 and second wafer 110 are both single-crystal substrates. In this embodiment, they are silicon wafers. Similarly to the fourth embodiment, the first wafer 109 includes a first region 2. Unlike the fourth embodiment, the first wafer 109 is not formed with openings 5a, and instead, a group of pixel apertures (a plurality of pixel apertures 9) are formed in each pixel area 12. The first wafer 109 has strips 6a between adjacent groups of pixel apertures. Similarly to the fourth embodiment, the second wafer 110 includes a first region and a second region 3, where openings 5b are formed. In this embodiment, the openings 5b also denote pixel areas 12. As illustrated in FIG. 6C, the deposition mask 1 has a layered structure composed of the first wafer 109 and second wafer 110.

The surface of the first wafer 109 and the surface of the second wafer 110 are both (100) planes. As illustrated in FIG. 6A, a notch 7a is formed on an end face of the first wafer 109 at a position shifted by an angle θ1 (0°<θ1<90°) from the point indicating the <110> orientation on the (100) plane. As illustrated in FIG. 6B, a notch 7b is formed on an end face of the second wafer 110 at a position shifted by an angle θ2 (0°<θ2<90°) from the point indicating the <110> orientation on the (100) plane. The angle θ2 is an angle in the opposite direction from the angle θ1. In this embodiment, the angle θ1 is a clockwise angle from the <110> orientation, and the angle θ2 is a counterclockwise angle from the <110> orientation.

As mentioned above, while pixel apertures 9 are formed in the first wafer 109, no openings 5 (openings 5a) are formed. The second wafer 110 is formed with a plurality of openings 5b such that the sides forming the strips 6b (sides of the openings 5b) are inclined at the angle θ2 to the cleavage direction of the second wafer 110 (<110> orientation on the (100) plane).

This way, the mechanical strength of the deposition mask 1 (strips 6b) can be enhanced.

Further, in this embodiment, the first wafer 109 and second wafer 110 are overlapped such that the position of the notch 7a of the first wafer 109 matches the position of the notch 7b of the second wafer 110. This way, the first wafer 109 and second wafer 110 are laminated so that the cleavage direction of the first wafer 109 and the cleavage direction of the second wafer 110 are different. One pair of strips 6a and 6b is equivalent to the strip 6 of the second embodiment.

This (making the cleavage directions of the plurality of substrates different) can enhance the mechanical strength of the deposition mask 1 (strips 6) even more, so that occurrence of defects in the deposition mask 1 can be reduced even more. For example, the mechanical strength of the deposition mask 1 (strips 6) against twist and torsion can be enhanced. This, in turn, enables more reliable production of high-quality organic electronic devices.

### Sixth Embodiment

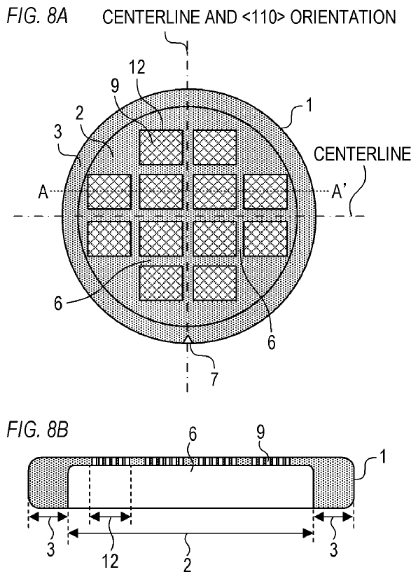

Hereinafter, a sixth embodiment of the present invention will be described with reference to FIG. 7A to FIG. 7D. FIG. 7A and FIG. 7B are diagrammatic plan views of a deposition mask 1 according to this embodiment viewed from below. FIG. 7C is a diagrammatic cross-sectional view illustrating a cross section of a plane passing line A-A′ in FIG. 7A and perpendicular to the deposition mask 1. FIG. 7D is a diagrammatic cross-sectional view illustrating a cross section of a plane passing line A-A′ in FIG. 7B and perpendicular to the deposition mask 1.

The deposition mask 1 of FIG. 7A and FIG. 7C will now be described. The deposition mask 1 is a silicon wafer in this embodiment, too. The surface of the deposition mask 1 is a (100) plane. As illustrated in FIG. 7A, a notch 7 is formed on an end face of the deposition mask 1 at the point indicating the <110> orientation on the (100) plane. A common semiconductor substrate is used for the deposition mask 1.

Similarly to the first embodiment, the first region 2 is formed with a plurality of openings 5, with strips 6 between adjacent openings 5. In this embodiment, the strip 6 is formed by a portion of one side of one of two openings 5 adjoining each other and a portion of one side of the other one of these two openings 5. Similarly to the first embodiment, the sides forming the strips 6 (sides of the openings 5) are inclined at an angle θ (0°<θ<90°) to the cleavage direction (<110> orientation on the (100) plane). In this embodiment, however, the plurality of openings 5 are aligned along a third direction parallel to the cleavage direction of the deposition mask 1, and a fourth direction perpendicular to the third direction. Namely, in the first embodiment, all the plurality of openings 5 are collectively inclined (rotated) from the reference position where the sides of the openings 5 are parallel or perpendicular to the direction in which the openings 5 are aligned, while in this embodiment, the plurality of openings 5 are each rotated.

Since the strips 6 of the deposition mask 1 in FIG. 7A and FIG. 7C are also inclined at the angle θ (0°<θ<90°) to the cleavage direction, the mechanical strength of the deposition mask 1 (strips 6) can be enhanced, so that occurrence of defects in the deposition mask 1 can be reduced. This, in turn, enables production of high-quality organic electronic devices.

The deposition mask 1 shown in FIG. 7B and FIG. 7D has pixel areas 12 where a plurality of pixel apertures 9 are arrayed instead of the rectangular areas forming the openings 5 in the deposition mask 1 shown in FIG. 7A and FIG. 7C. Other features of the deposition mask 1 shown in FIG. 7B and FIG. 7D are the same as those of the deposition mask 1 shown in FIG. 7A and FIG. 7C. Therefore, the deposition mask 1 shown in FIG. 7B and FIG. 7D (strips 6) can also have enhanced mechanical strength, so that occurrence of defects in the deposition mask 1 can be reduced. This, in turn, enables production of high-quality organic electronic devices.

### Seventh Embodiment

Hereinafter, a seventh embodiment of the present invention will be described with reference to FIG. 8A to FIG. 8E. FIG. 8A is a diagrammatic plan view of a deposition mask 1 according to this embodiment viewed from below. FIG. 8B is a diagrammatic cross-sectional view illustrating a cross section of a plane passing line A-A′ in FIG. 8A and perpendicular to the deposition mask 1. The deposition mask 1 is a silicon wafer in this embodiment, too. The surface of the deposition mask 1 is a (100) plane. The first region 2 includes a plurality of pixel areas 12. FIG. 8C and FIG. 8D are diagrammatic plan views illustrating part of the pixel area 12 to a larger scale.

As illustrated in FIG. 8C and FIG. 8D, the plurality of pixel apertures 9 are arrayed in a matrix along a row direction and a column direction perpendicular to the row direction. In this case, the spacing between pixel apertures 9 is the smallest along the row direction or column direction. Therefore, the deposition mask 1 is weakest in mechanical strength and prone to defects between the pixel apertures 9 in the row direction or column direction.

Therefore, as shown in FIG. 8E, the angle φ between the above-mentioned row direction or column direction and the cleavage direction (<110> orientation on the (100) plane) is set in the range of 0°<φ<90°.

This way, the mechanical strength of the deposition mask 1 (between the pixel apertures 9) can be enhanced, so that occurrence of defects in the deposition mask 1 can be reduced. This, in turn, enables production of high-quality organic electronic devices.

The mechanical strength is relatively high when the angle φ to the cleavage direction is in the range of 10°≤φ≤35°. The mechanical strength is highest when the angle φ to the cleavage direction is in the range of 26.5±5°. Therefore, the angle φ should preferably be in the range of 10°≤φ≤35°, and more preferably be in the range of 26.5±5°.

While the <110> orientations on the (100) plane are referred to as cleavage directions in the embodiments described above, directions perpendicular to the <110> orientations can also be considered cleavage directions. Other directions than the <110> orientations can also be cleavage directions, in cases where the surface of the substrate is not the (100) plane, or a substrate that is not a silicon wafer is used.

According to the present invention, a deposition mask made of single-crystal silicon and having high mechanical strength can be provided, and further, a high-quality organic electronic device can be provided.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-082705, filed on May 14, 2021, which is hereby incorporated by reference herein in its entirety.

What is claimed is:

1. A deposition mask comprising a first substrate that is a single-crystal substrate, wherein
a first region that is at least a portion of the first substrate, includes a plurality of rectangular areas each of which has one or a plurality of openings,
a substrate thickness in the rectangular area is smaller than a substrate thickness in an area that is a part of the first region and is not the rectangular area, and
an angle θ1 between a side of the rectangular area and a cleavage direction of the first substrate is in a range of 0°<θ1<90°.

2. The deposition mask according to claim 1, wherein the first substrate includes the first region and a second region surrounding the first region.

3. The deposition mask according to claim 1, wherein
the first substrate is a silicon wafer of which a surface is a (100) plane, and
the cleavage direction is a <110> orientation.

4. The deposition mask according to claim 1, wherein the angle θ1 is in a range of 10°≤θ1≤35°.

5. The deposition mask according to claim 1, wherein the angle θ1 is in a range of 26.5±5°.

6. The deposition mask according to claim 1, wherein the plurality of rectangular areas are a plurality of openings.

7. The deposition mask according to claim 1, wherein a plurality of openings are arranged in the rectangular area.

8. The deposition mask according to claim 7, wherein sides of the plurality of openings do not coincide with the cleavage direction of the first substrate, in a plane parallel to the first substrate.

9. The deposition mask according to claim 7, wherein
the plurality of openings are arrayed in a matrix having a row direction and a column direction perpendicular to the row direction, and
an angle φ between the row direction or the column direction and the cleavage direction is in a range of 0°<φ<90°.

10. The deposition mask according to claim 9, wherein the angle φ is in a range of 10°≤φ≤35°.

11. The deposition mask according to claim 9, wherein the angle φ is in a range of 26.5±5°.

12. The deposition mask according to claim 1, wherein a plurality of substrates including the first substrate are laminated.

13. The deposition mask according to claim 12, wherein
the plurality of substrates include the first substrate and a second substrate that is a single-crystal substrate, and
an angle θ2 between a side of the rectangular area and a cleavage direction of the second substrate is different from the angle θ1 between the side of the rectangular area and the cleavage direction of the first substrate.

14. The deposition mask according to claim 13, wherein the angle θ2 is 0°.

15. The deposition mask according to claim 13, wherein the angle θ2 is in a range of 0°<θ2<90° in an opposite direction from the angle θ1.

16. The deposition mask according to claim 1, wherein
the plurality of rectangular areas are aligned along a first direction inclined at the angle θ1 relative to the cleavage direction of the first substrate and a second direction perpendicular to the first direction, and
the rectangular area has a side parallel to the first direction and a side parallel to the second direction.

17. The deposition mask according to claim 1, wherein the plurality of rectangular areas are aligned along a third direction parallel to the cleavage direction of the first substrate and a fourth direction perpendicular to the third direction.

18. A deposition mask comprising a single-crystal substrate, wherein
in at least a portion of the single-crystal substrate, a plurality of openings arrayed in a matrix, and
an angle φ between each of a row direction and a column direction, in which the plurality of openings are arrayed, and a cleavage direction of the single-crystal substrate is in a range of 0°<φ<90°.

19. The deposition mask according to claim 18, comprising a third region including a region where the plurality of openings are provided, and a fourth region that is other than the third region, wherein
a substrate thickness in the third region is smaller than a substrate thickness in the fourth region.

20. A manufacturing method of an organic electronic device, the method comprising:
placing a deposition mask to face a target substrate; and
depositing an organic material on the target substrate through the deposition mask, wherein
the deposition mask includes a first substrate that is a single-crystal substrate,
a first region that is at least a portion of the first substrate, includes a plurality of rectangular areas each of which has one or a plurality of openings,
a substrate thickness in the rectangular area is smaller than a substrate thickness in an area that is a part of the first region and is not the rectangular area, and
an angle θ1 between a side of the rectangular area and a cleavage direction of the first substrate is in a range of 0°<θ1<90°.
